(19) United States
(12) Patent Application Publication
(10) Pub. No.: US 2011/0293832 A1
(43) Pub. Date: Dec. 1, 2011

(54) Method and apparatus for depositing thin layers of polymeric para-xylylene or substituted para-xylylene

(75) Inventors: Markus Gersdorff, Herzogenrath (DE); Pagadala Gopi Baskar, Duisburg (DE); Nico Meyer, Aachen (DE)

(73) Assignee: AIXTRON AG, Herzogenrath (DE)

(21) Appl. No.: 12/995,170

(22) PCT Filed: Jun. 3, 2009
(86) PCT No.: PCT/EP2009/056768

§ 371 Date: Dec. 7, 2010

(30) Foreign Application Priority Data
Jun. 3, 2008 (DE) 10 2008 026 974.3

(51) Int. Cl. C23C 16/455; C23C 16/46

(52) U.S. Cl. 427/255.28; 118/724; 118/725

(57) ABSTRACT

The invention relates to an apparatus and a method for depositing one or more thin layers of polymeric para-xylylene. Said apparatus comprises a heated evaporator (1) used for evaporating a solid or liquid starting material. A supply pipe (11) for a carrier gas extends into said evaporator (1). The carrier gas conducts the evaporated starting material, in particular the evaporated polymer, into a pyrolysis chamber (2) which is located downstream of the evaporator (1) and in which the starting material is decomposed. The apparatus further comprises a deposition chamber (8) which is located downstream of the decomposition chamber (2) and encompasses a gas inlet (3) through which the decomposed product conducted by the carrier gas is admitted, a susceptor (4) which has a supporting surface (4′) opposite the gas inlet (3) in order to support a substrate (7) that is to be coated with the polymerized decomposed product, and a gas outlet (5). In order to be able to deposit a thin polymer layer that especially has a homogeneous layer thickness and covers a large area, the gas inlet (2) forms a planar gas distributor which has a gas discharge surface (3′) that extends parallel to the supporting surface (4′) and is fitted with a plurality of gas discharge ports (6) distributed across the entire gas discharge surface (3′).

The invention relates to an apparatus for depositing one or more thin layers of polymeric para-xylylene or substituted para-xylylene, comprising a heated evaporator for evaporating a solid or liquid starting material, in particular in the form of a polymer, in particular a dimer, into which evaporator there extends a carrier-gas supply line for a carrier gas, by which carrier gas the evaporated starting material, in particular the evaporated polymer, in particular dimer, is transported into a heatable decomposition chamber, in particular a pyrolysis chamber, which is located downstream of the evaporator and in which the starting material is decomposed, in particular into a monomer, and comprising a deposition chamber, which is located downstream of the decomposition chamber and has a gas inlet, through which the decomposition product, in particular monomer, transported by the carrier gas, enters, a susceptor, which has a coolable supporting surface opposite the gas inlet for supporting a substrate that is to be coated with the polymerized decomposition product, in particular monomer, and a gas outlet, through which the carrier gas and an unpolymerized part of the decomposition product, in particular monomer, exits, the gas inlet forming a planar gas distributor, which has a heatable gas discharge surface that extends parallel to the supporting surface and has a multiplicity of gas discharge ports distributed over the entire gas discharge surface.

The invention additionally relates to a method for depositing one or more thin layers of polymeric material, in particular para-xylylene, or substituted para-xylylene, a solid or liquid starting material, formed in particular by a polymer, in particular a dimer, being evaporated in an evaporator, the starting material, in particular the dimer, being transported by means of a carrier gas from the evaporator through a carrier gas supply line into a decomposition chamber, in particular a pyrolysis chamber, decomposed in the decomposition chamber, preferably pyrolytically, in particular into a monomer, the decomposition product, in particular monomer, being transported by the carrier gas from the decomposition chamber into a deposition chamber, in which a substrate rests on a supporting surface of a susceptor, and flowing there through a gas inlet into the deposition chamber, the decomposition product, in particular monomer, being discharged in a direction perpendicular to the substrate surface together with the carrier gas from gas discharge ports of a gas discharge surface, extending parallel to the supporting surface, of a planar gas distributor formed by the gas inlet and polymerizing on the surface of the substrate as a thin layer, and the carrier gas and an unpolymerized part of the decomposition product, in particular monomer, exiting out of the process chamber from a gas outlet, the supporting surface being cooled and the gas discharge surface that lies opposite the supporting surface being heated in such a way that the surface temperature of the gas discharge surface is higher than the surface temperature of the supporting surface.

U.S. Pat. No. 6,709,715 B1, U.S. Pat. No. 6,362,115 B1 and U.S. Pat. No. 5,958,510 A disclose an apparatus for depositing p-xylylenes in which the starting material is fed by means of a carrier gas to a decomposition chamber, is decomposed there, the decomposition products are brought to the gas inlet of a process chamber, introduced through the gas inlet into the process chamber and polymerized on a cooled substrate. The gas inlet system has a plate which is provided with a multiplicity of openings and extends parallel to the substrate over the entire surface area thereof.

U.S. Pat. No. 4,945,856 describes a method in which a solid starting material that is a dimeric para-xylylene is brought into the form of a gas in a gas generator. This gas is conducted through gas lines into a pyrolysis chamber. There, the dimer is decomposed into a monomer. The monomer is conducted by the carrier gas through a gas line into a process chamber. There, it is admitted through a gas inlet formed by a pipe opening, in order to condense there on a substrate resting on a supporting surface of a susceptor. The process chamber additionally has a gas outlet, from which the monomer that is not polymerized on the substrate surface can be discharged. In a cooling trap located downstream of the gas outlet, the monomer is frozen out of the carrier gas. The pressure in the process chamber is set by means of a vacuum pump, which is located downstream of the cooling trap.

The para-xylylene copolymers used are described by U.S. Pat. No. 3,288,728. They are C, N, D polymers of the parylene family, which at room temperature are in the solid powdery phase or in the liquid phase.

It is known from “Characterization of Parylene Deposition Process for the Passivation of Organic Light Emitting Diodes”, Korean J. Chem. Eng., 19(4), 722 -727(2002) to passivate, in particular encapsulate, OLEDs with layers of poly-p-xylyene and derivatives thereof. Otherwise, it is known to provide various large-area substrates with a parylene coating in a vacuum. For example, glass, metal, paper, paint, plastics, ceramic, ferrite and silicone are coated with a pore-free, transparent polymer film by condensation from the gas phase. This exploits the hydrophobic, chemically resistant and electrically insulating property of the polymeric coating.

It is an object of the invention to propose measures by which a polymer layer that covers a large surface area, is thin and, in particular, is homogeneous with regard to the layer thickness, can be deposited.

The object is achieved by the invention specified in the claims, where each claim represents an independent way of achieving the object and can be combined with any other claim.

First and foremost, a planar gas distributor is proposed as a gas inlet. With the planar gas distributor, it is possible for deposition material to be supplied uniformly to the gas phase above the substrate. Layers with layer thicknesses in the submicron range can be deposited homogeneously over the entire substrate surface, which may be larger than half a square meter. This makes the method suitable for use in semiconductor technology. With the apparatus according to the invention and the method according to the invention, it is possible for dielectric layers to be deposited in the production of field effect transistors as a gate insulating layer. In particular, 200 nm thick gate insulations are deposited onto large-area, pre-structured substrates. The deposition of the dielectric insulating layers may be performed in a structured manner. For this purpose, a shadow mask may be placed onto the substrate. The method according to the invention or the apparatus according to the invention can be used for any type of large-area coating. In particular, use for the production of e-paper is envisaged. This involves coating a flexible, thick, in particular gold-structured substrate with the polymer. The method and the apparatus can also be used in the case of TFT technology. The planar gas distributor used according to the invention has a gas discharge surface which has a screen-like structure. It has a multiplicity of gas discharge ports which are distributed substantially uniformly over the gas discharge surface and through which a thin gas jet is in each case discharged, as from a nozzle, in the direction of the substrate. The size of the gas discharge surface corresponds substantially to the size of the substrate which is at a distance from it. The gas discharge surface and the supporting surface of the susceptor on which the substrate or the substrates lie(s) run parallel to one another and preferably in the horizontal plane. The distance between the gas discharge surface and the supporting surface of the susceptor on which the substrate rests is chosen such that a substantially uniform gas front of the gas emerging from the gas discharge ports arrives at the substrate. The gas discharge ports are accordingly close together. The individual “gas jets” emerging there combine to form the uniform gas front mentioned. The process temperature of the susceptor is lower than the process temperature of the planar gas distributor. The temperature of the planar gas distributor lies in the range between 150° C. and 250° C. The temperature of the susceptor lies in the range from −30° C. to 100° C. To avoid energy transfer by way of thermal radiation from the planar gas distributor to the susceptor, the planar gas distributor, and in particular the gas discharge surface directed toward the susceptor, has a very low emissivity. The emissivity lies in the range ε<0.04. This is achieved by polishing or gold-coating the surface of the planar gas distributor and, in particular, the gas discharge surface. The highly polished planar gas distributor acts with a minimized radiation output on the surface to be coated of the substrate. Since the surface temperature of the gas discharge surface is much higher than the surface temperature of the supporting surface, a vertical temperature gradient forms within the gas phase of the deposition chamber that extends between the gas discharge surface and the supporting surface. The substrate lies flat on the supporting surface and is consequently in thermally conducting contact with the susceptor. In spite of the minimized radiation output of the coated, heated surface of the gas inlet, the surface of the substrate may heat up. However, the heat flows away into the susceptor via the thermally conducting contact between the underside of the substrate and the supporting surface. The susceptor is preferably cooled. The planar gas distributor may consist of aluminum or high-grade steel. The gas flow discharged from the gas discharge ports as from nozzles, consisting of a carrier gas and the monomer, passes as a gas front to the surface of the substrate. On the surface, the monomer is adsorbed. The adsorbed monomer grows there in a polymerization growth process to form a layer. The growth rate can be influenced or controlled by way of the temperature gradient, which is partly influenced by the planar gas distributor. This temperature gradient makes a high growth efficiency possible. Use of the planar gas distributor makes coating over a large area possible, beginning in the range of 150 mm×150 mm up to 1000 mm×1000 mm. Substrates of this size can be coated uniformly with the polymer material. The molecules that do not contribute to the growth of the film are conducted out of the process chamber from the monomer gas phase by way of a heated gas outflow. A vacuum pump pumps the waste gas through a heated gas outflow between 50° C. and 250° C. into a cooling trap, where the monomer freezes. The process pressures lie at 0.05 mbar to 0.5 mbar. The pressure loss over the planar gas distributor is less than 0.5 mbar. This makes a decomposition pressure (pyrolysis pressure) of less than 1 mbar possible. To bring the substrate holder to the desired laterally homogeneous surface temperature, it has a temperature control device, which may be formed by temperature-control fluid channels, through which there flows a fluid that is liquid in the temperature range between −30° C. and 100° C. Two temperature-control fluid channels which run parallel to one another and through which flow passes in opposite directions are preferably provided.

The planar gas distributor also has temperature control means. Here, too, they may be channels through which a temperature-controlled fluid flows. The channels are preferably disposed in a plate of the planar gas distributor that forms the gas discharge surface. The passages, which open out in the gas discharge surface, may be formed by small tubes. The channels mentioned can run in the space between the small tubes. Instead of the channels through which a heating fluid flows, however, electrically heated heating coils or heating wires may also be located there. Resistance heating of this kind of the gas discharge surface is preferred. On the rear of the plate there is a gas volume, which is fed by an input distributor. Into said input distributor there extends a heated gas supply line, through which the carrier gas with the polymer is transported into the gas inlet. The walls of the process chamber are likewise heated. They are kept at temperatures in the range between 150° C. and 250° C. The distance between the gas discharge surface and the substrate surface or the supporting surface lies in the range between 10 mm and 50 mm and may optionally be adjusted.

Suitable as substrates are display substrates, silicon wafers or substrates of plastics or of paper. In the apparatus described above and by the method according to the invention, a dielectric layer is deposited onto the substrates. The substrate may be a dielectric substrate or a non-dielectric substrate or else a metal or a semiconductor. The substrate is preferably pre-structured, for example semiconductor circuits and, in particular, transistors may have been applied to it. The underside of the substrate lies in full-area contact with the supporting surface of the susceptor, which may be formed by a cooling block that consists of aluminum or of copper. The susceptor may be disposed in the process chamber in a statically fixed state. However, it is also envisaged that it may rotate about a central, in particular vertical, axis. In the case of the method according to the invention, a carrier gas, which may be argon, nitrogen or helium, is provided by a mass flow controller and is conducted to an evaporator by way of a supply line, which can be closed by means of a valve. In the evaporator there is a liquid or solid starting material, which is a parylene dimer. At a temperature between 50° C. and 200° C., the dimer evaporates and is conducted to a pyrolysis oven by means of the carrier gas, through a gas line which is heated and can be closed by means of a valve. The temperature there at a pressure of <1 mbar is 350° C. to 700° C. The dimer is decomposed pyrolytically in the oven into a monomer, which is transported by way of a likewise heated gas line into an input distributor of a process chamber. The carrier gas and the monomer carried by it are then admitted to the chamber of the planar gas distributor that is to the rear of the plate and has the discharge ports. With a low pressure loss, this process gas flows through the gas discharge ports distributed uniformly over the gas discharge surface and reaches the surface of the substrate as a gas front. There, the monomers adsorb and polymerize to form a dielectric layer at growth rates of up to 2 μm/s. The dwell time of the dimers in the pyrolysis oven and the pressure gradient there are set by means of the mass flow controller or by way of the pressure in the process chamber. The coating area, extending parallel to the planar gas distributor, is preferably more than half a square meter. The connecting lines from the source, formed by the evaporator, to the chamber and to the cooling trap are heated to a temperature that lies above the polymerization temperature. This also applies to the actively heated gas distributor. Said distributor is highly polished or gold-coated. Together with the other structural design and process engineering features, the planar introduction of the process gas over substantially the entire surface area that is taken up by the substrate achieves a high efficiency. Only a minimal amount of the monomer introduced into the process chamber does not polymerize on the substrate and disappears as waste in the cooling trap.

The apparatus according to the invention or the method according to the invention serves in particular for depositing polymeric para-xylyene or substituted para-xylyene. For example, parylene C may be used. The transport of the evaporated material takes place by a carrier gas, which is, for example, N₂ or argon or some other suitable inert gas. The decomposition of the starting material only preferably takes place pyrolytically. It is also envisaged to decompose the starting material in some other way, for example assisted by a plasma. The starting material to be decomposed does not necessarily have to be a dimer. The starting material may additionally also be decomposed in a cascading manner into a monomer or into further decomposition products. Of particular importance, furthermore, is the polymer chain formation on the coating object.

An exemplary embodiment of the invention is explained below on the basis of accompanying drawings, in which:

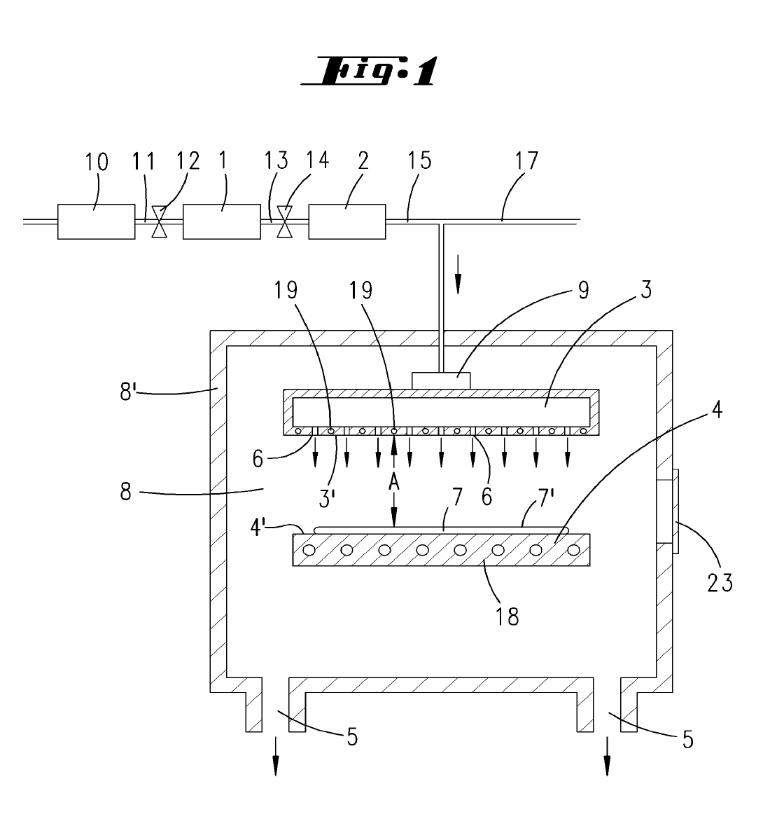

FIG. 1 schematically shows the main component parts of the coating apparatus and, in particular, the internal structure of the process chamber,

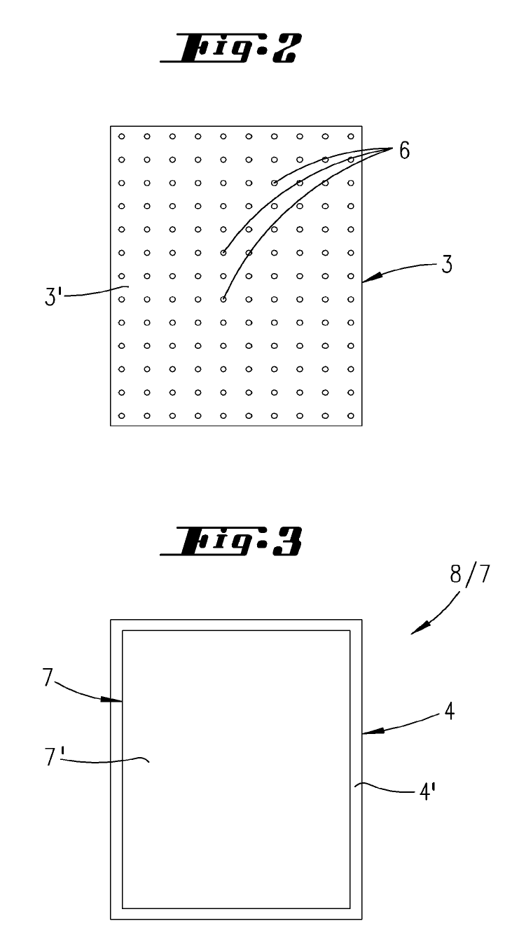

FIG. 2 shows the plan view of a gas discharge surface and

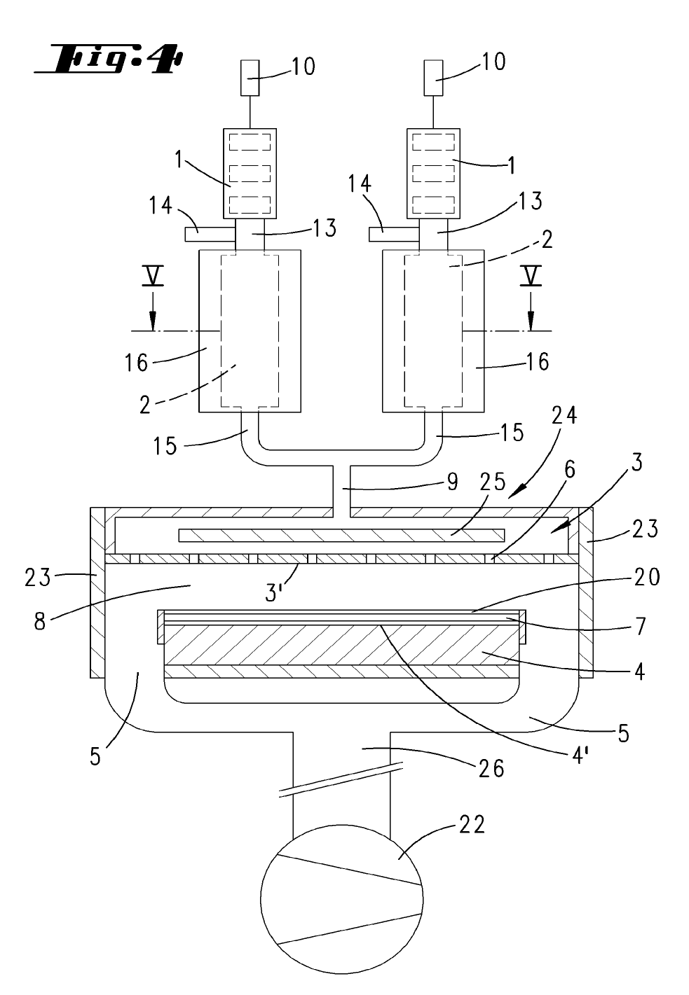

FIG. 3 shows the plan view of the carrying surface of a susceptor with a substrate lying on it,

FIG. 4 shows a schematic representation of a further exemplary embodiment,

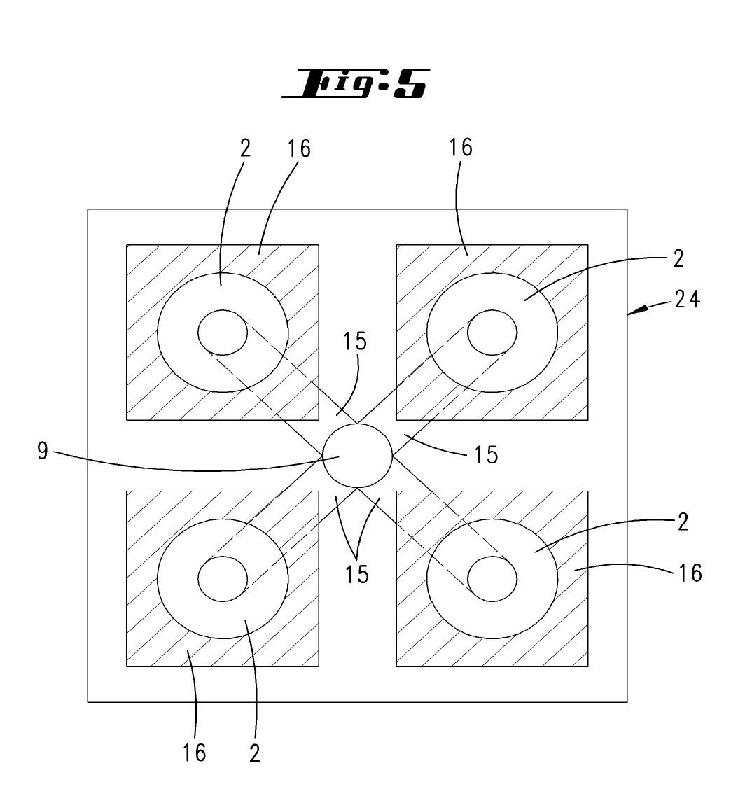

FIG. 5 shows a section along the line V-V in FIG. 4,

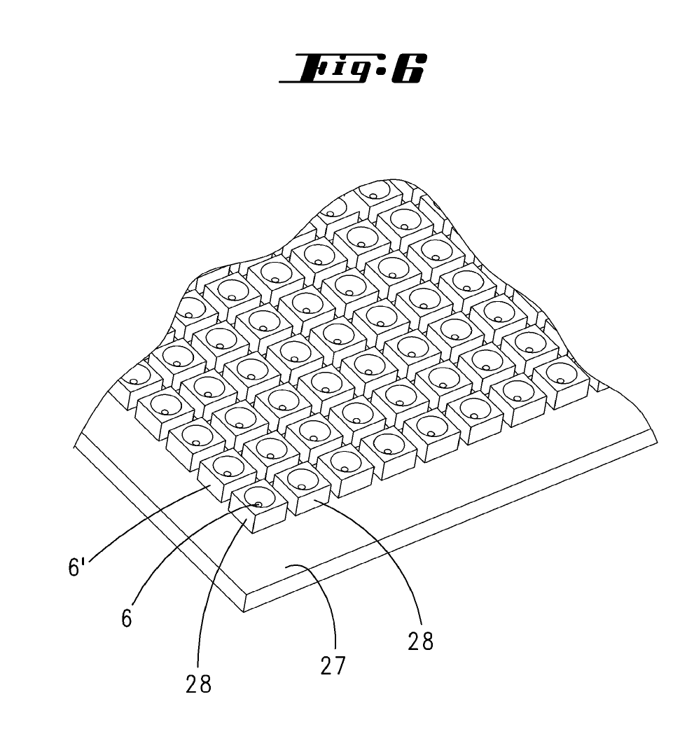

FIG. 6 shows a perspective representation of part of an inner plate of the lower wall of the gas inlet 3, inverted,

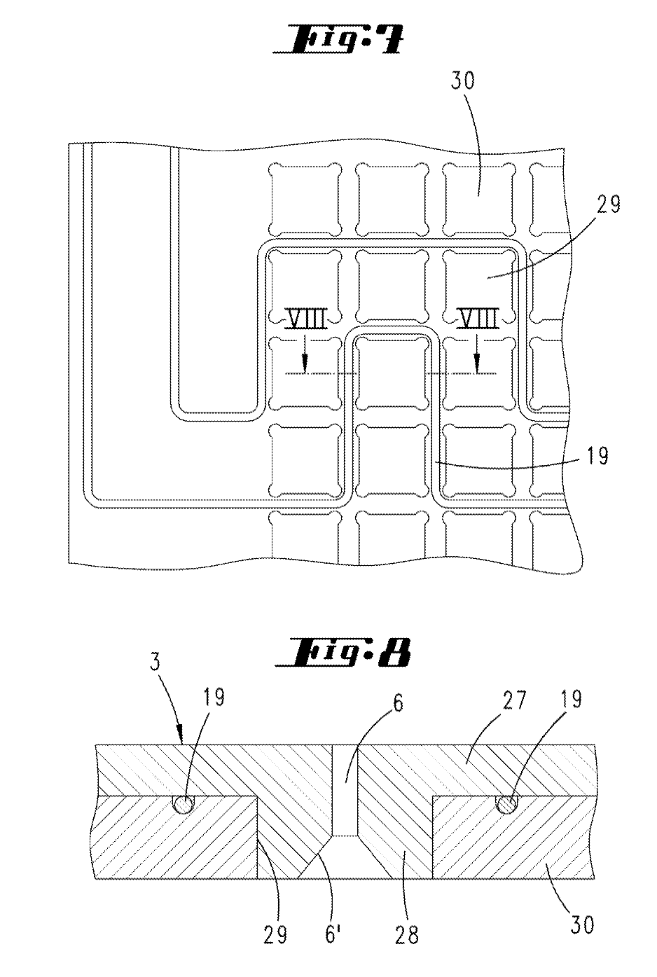

FIG. 7 shows a partial representation of an outer wall 30 of the gas inlet, likewise inverted, and

FIG. 8 shows a section through the lower wall of the gas inlet in the region of a gas discharge port.

The mass flow of a carrier gas, which may consist of helium, argon or nitrogen, is set by a mass flow controller 10. The carrier gas flows through a gas line 11, which can be closed by a valve 12, into an evaporator 1.

The evaporator 1 has dishes or containers of some other form that store a liquid or solid starting material, which is a material of the parylene family, in particular C, N, D polymer para-xylyenes. The powder or the liquid is heated to a source temperature of 50° C. to 200° C. by a heater that is not represented. The volume of the source container is designed in relation to the mass flow of the carrier gas flowing through the evaporator such that the gas phase and the solid bodies or liquid phase are substantially in thermal equilibrium. By means of the carrier gas flow, the evaporated starting material, which is preferably a dirtier, is conducted through a heated gas line 13, which can likewise be closed by a valve 14, into a pyrolysis chamber 2.

The pyrolysis chamber 2 can be heated up to temperatures in the range between 350° C. to 700° C. by a heater that is not represented. At a total pressure in the chamber of less than 1 mbar, the dimer is pyrolytically decomposed into a monomer.

By way of a likewise heated gas line 15, into which there also extends an additional gas line 17, the monomer is introduced together with the carrier gas into the process chamber. The additional supply line 17 makes it possible to introduce additional material into the process chamber. By way of the supply line 17, which is likewise heated, the same materials or other materials can be admixed with the starting material.

Heating of the previously mentioned gas lines 11, 13, 15 and 17 may take place by way of heating sleeves. These may be heated up by means of heating coils. However, it is also possible to locate the lines together with the evaporation chamber 1 and the process chamber 2 in a heated housing. This housing may be disposed spatially above or alongside the actual process chamber.

Inside the process chamber 8, the walls 8′ of which may be heated, there is a gas inlet 3 in the upper region. This gas inlet has an input distributor 9, into which the gas line 15 extends. The main component part of the gas inlet 3 is a planar gas distributor, which forms a central chamber into which the gas enters from the input distributor 9. The base of the chamber of the planar gas distributor 3 may have a rectangular or circular shape. In the exemplary embodiment (FIG. 2), the base of the chamber 3 has a rectangular shape with edge lengths of 700 and 800 mm. The plate forming the base of the gas distribution chamber has a plurality of channels 19, through which temperature control fluid flows in order to keep the plate at a temperature in the range between 150° C. and 250° C. Instead of the channels 19, however, heating coils or the like may also be provided. A pertinent feature is a multiplicity of gas discharge ports 6 arranged in uniform distribution over the surface area. Through these thin, capillary-like gas discharge ports 6, the carrier gas and the monomer carried by it enter into the process chamber 8 in the form of “gas jets”. This takes place with a pressure difference of less than 0.5 mbar.

The outer surface of the planar gas distributor 3 forms a gas discharge surface 3′, which extends in the horizontal direction.

Extending parallel to the gas discharge surface is a supporting surface 4′ of a susceptor 4. The supporting surface 4′ is spaced apart from the gas discharge surface 3′ by a distance A, which is approximately 10 mm to 50 mm. The supporting surface 4′, which is shown in FIG. 3 and formed by the upper side of a susceptor 4, is approximately the same size as the gas discharge surface 3′, it being possible for the latter to be even slightly larger.

The susceptor 4 is formed by a cooling block. The latter consists of aluminum or of copper and has a plurality of temperature-control medium channels 18, through which a fluid can flow. Two channels may be provided, disposed in a meandering form, running parallel to one another and flowed through in opposite directions. They actively cool the susceptor 4 and, in particular, its surface 4′ that serves as a supporting surface for the substrate 7.

Lying in full-area surface contact on the supporting surface 4′ is a substrate 7. It may be a dielectric substrate or a non-dielectric substrate, for example a display, a silicon wafer or paper. The substrate 7 lies in full-area contact on the supporting surface 4′, so that heat transfer from the substrate 7 to the susceptor 4 is possible.

In the region of the base of the process chamber 8 there are two gas outlet ports 5, which are connected by a heated line that is not represented to a cooling trap that is not represented. The cooling trap, which is for example kept at the temperature of liquid nitrogen, freezes parylene present in the waste gas. Downstream of the cooling trap there is a vacuum pump, not represented, which is pressure-regulated and with which the internal pressure inside the process chamber 8 can be adjusted.

The process pressure in the process chamber 8 is set in a range from 0.05 mbar to 0.5 mbar. The temperature of the susceptor lies well below the temperature of the process chamber walls 8′ or the temperature of the planar gas distributor 3, which lies in the range between 150° C. and 250° C. To minimize heating up of the substrate by thermal radiation from the planar gas distributor 3, the latter is highly polished and/or gold-coated. Its emissivity ε lies below 0.04.

The gas exiting from the gas discharge ports 6 arranged in the manner of a shower head impinges as a gas front on the surface 7′ of the substrate 7, where the monomers are adsorbed. The adsorbed material polymerizes there to form a film at growth rates of up to 2 μm/s. The lateral homogeneity of the surface temperature of the supporting surface 4′ is ±0.5° C.

The reference numeral 23 indicates an unloading and loading opening, which can be closed in a vacuum-tight manner and is provided in the side wall of the process chamber in order for the substrate 7 to be handled.

In the case of the exemplary embodiments represented in FIGS. 4 and 5, the gas inlet 3 is fed by a total of four pyrolysis chambers 2, each with upstream evaporators 1. The deposition chamber 8, which can also be referred to as a process chamber, is located in an approximately cuboidal reactor housing 24. Under the rectangular top surface of the reactor housing 24 there is a gas inlet 3, which takes up almost the entire inner side of the top surface and has a distributing chamber, into which there opens an input distributor 9 in the form of a pipe of a large diameter. Extending in front of the mouth of the pipe 9 is a plate 25, by which the process gas entering the chamber of the gas inlet 3 is distributed. Parallel to the top plate of the reactor housing 24 there is a perforated plate with ports 6, which forms a gas discharge surface 3′ that extends parallel to the top plate of the reactor housing 24. The multiplicity of ports 6 are distributed uniformly over the gas discharge surface 3′.

In the plate forming the gas discharge surface 3′, which may he of a multilayered structure, there are temperature control means that are not represented. The temperature control means are electrically heated heating wires. Instead of resistance heating such as this, the plate forming the gas discharge surface 3′ may, however, also have channels through which there flows a temperature-controlled fluid.

If heating wires are used as the temperature control means, they are of a multilayered structure. Two plates kept apart from one another, one of which forms the lower wall of the gas volume and the other of which forms the gas discharge surface 3′, are connected to one another by means of small tubes, the small tubes forming the ports 6. Said heating wires run in the space between the small tubes.

At a distance of approximately 25 mm to 50 mm below the gas discharge surface 3′, there is a susceptor 4. A substrate 7 lies on the supporting surface 4′ of the susceptor 4 that is facing the gas discharge surface 3′. Positioning means that are not represented are provided in order to position the pre-structured substrate 7 exactly on the supporting surface 4′. Above the substrate 7 there is a shadow mask 20, which is positioned exactly in relation to the substrate 7 by suitable mask holders. The temperature of the susceptor 4 can be controlled at a temperature which is much lower than the temperature of the gas inlet 3 by temperature control means that are not represented. The temperature of the gas discharge surface 3′ is at least 50° C. and preferably at least 100° C. higher than the temperature of the supporting surface 4′. The substrate 7 rests on the supporting surface 4′ in such a way that heat which is transferred as radiant heat from the gas inlet 3 to the substrate 7 can be diverted to the susceptor 4. This ensures that the surface temperature of the substrate 7 is only slightly higher than the surface temperature of the supporting surface 4′.

The gas outlet ports are formed by pipes of a large diameter. These pipes extend into a pipe 26, which likewise has a large diameter and which is connected to a pump 22.

Vertically above the reactor housing 24 there are a total of four pyrolysis chambers 2, which are flowed through in the vertical direction from top to bottom. Each pyrolysis chamber 2 is surrounded by a heating jacket 16, which supplies the process heat required for the pyrolysis.

Above the total of four pyrolysis chambers 2 there are evaporators 1, which are associated with their respective pyrolysis chamber 2 and are likewise connected to the pyrolysis chamber 2 by pipelines 13 of a large diameter. The pipelines 13 each have valves 14. In the pipeline 26 leading to the pump 22 there is a control valve, which is not represented but by which the pressure in the process chamber 8 can be regulated. For this purpose, a pressure sensor that is not represented is located inside the reactor housing 24.

The reference numeral 23 indicates gates which can be opened in order to load/unload the process chamber with/of substrates or in order to introduce masks 20 into the process chamber.

In the evaporator 1 there are dishes, which are indicated in FIG. 4 by dashed lines and in which the starting substance is stored at an evaporation temperature of approximately 110° C. A carrier gas flow of approximately 500 sccm, controlled by the MFC 10, flows through the evaporator 1. In the pyrolysis cell 2, the dimer transported by the carrier gas is pyrolytically decomposed. The flow rate is set by means of the pump 22 in such a way that the dwell time of the gas within the pyrolysis chamber 2 is of the order of milliseconds, that is to say approximately 0.5 to 5 ms. The pumping output and the flow resistances of the overall apparatus are chosen here such that a total pressure of approximately 1 mbar prevails inside the pyrolysis chambers 2.

Through the total of four gas lines 15, the decomposition products are conducted by the carrier gas into the input distributor 9, which leads to the shower-head gas inlet 3. There, the process gas is distributed uniformly and enters into the process chamber 8 through the gas discharge ports 6.

The diameters of the gas discharge ports 6 and the number thereof are adapted here to the flow resistance of the overall installation and the pumping output of the pump 22 in such a way as to obtain a pressure gradient at the ports such that a process pressure of approximately 0.1 mbar prevails inside the process chamber 8. The pressure in the process chamber 8 is consequently lower than the pressure in the pyrolysis chamber 2 by a factor of approximately 10.

By means of the heating sleeves that are not represented in FIG. 4, the gas lines 15 and 9 as well as the inlet element 3 are kept at a temperature which is greater than the polymerization or condensation temperature of the decomposition products transported by the carrier gas. The gas discharge surface 3′ of the gas inlet 3 may be heated by means of heating wires. The gas discharge surface 3′ facing the susceptor 4 is gold-coated and highly polished.

The process gas that has been admitted into the process chamber 8 condenses on the surface of the pre-structured substrate 7. The latter rests on the supporting surface 4′ of the susceptor 4 and is covered by the shadow mask 20 in such a way that the polymerization only takes place at defined portions of the surface of the substrate 7.

The susceptor 4 is cooled to polymerization temperature.

In the case of the exemplary embodiment represented in FIGS. 4 and 5, no cooling trap is provided. Unused process gas can condense on the walls of the pipes 5, 26 of a large diameter. These pipes must be cleaned from time to time.

The structures of the mask lie in the range of 50×50 μm. Layer thicknesses in the range between 10 nm and 2 μm are deposited at growth rates of approximately 100 nm/s.

The lower wall of the gas inlet 3, which with its downwardly facing surface forms the gas discharge surface 3′, preferably comprises two plates. An inner plate 27, a portion of which is shown inverted in FIG. 6, has a multiplicity of bores 6, which open out into flared discharge ports 6′. The flared discharge ports 6′ are located in projections with a square base area. These projections protrude downward into square recesses 29 in a lower plate 30. The upper wall of the lower plate 30 has grooves, in which heating coils 19 are located. The grooves run in the region between the openings 29. In the assembled state, the heating coils 19 consequently run in the region between the projections 28.

All features disclosed are (in themselves) pertinent to the invention. The disclosure content of the associated/accompanying priority documents (copy of the prior patent application) is also hereby incorporated in full in the disclosure of the application, including for the purpose of incorporating features of these documents in claims of the present application.

1. An apparatus for depositing one or more thin layers of polymeric para-xylylene or substituted para-xylylene, comprising a heated evaporator (1) for evaporating a solid or liquid starting material, in particular in the form of a polymer, in particular a dimer, into which evaporator (1) there extends a carrier-gas supply line (11) for a carrier gas, by which carrier gas the evaporated starting material, in particular the evaporated polymer, in particular the dimer, is transported into a heatable decomposition chamber (2), in particular a pyrolysis chamber, which is located downstream of the evaporator (1) and in which the starting material is decomposed, in particular into a monomer, and comprising a deposition chamber (8), which is located downstream of the decomposition chamber (2) and has a gas inlet (3), through which the decomposition product, in particular a monomer, transported by the carrier gas, enters, a susceptor (4), which has a coolable supporting surface (4′) opposite the gas inlet (3) for supporting a substrate (7) that is to be coated with the polymerized decomposition product, in particular the monomer, and a gas outlet (5), through which the carrier gas and an unpolymerized part of the decomposition product, in particular the monomer, exits, the gas inlet forming a planar gas distributor (3), which has an actively heatable gas discharge surface (3′) that extends parallel to the supporting surface (4′) and has a multiplicity of gas discharge ports (6) distributed over the entire gas discharge surface (3′),
characterized in that the actively heatable gas discharge surface (3′) is highly reflective and has an emissivity of ε<0.04.

2. An apparatus according to claim 1, characterized in that the planar gas distributor consists of highly polished metal, especially gold-coated metal, in particular aluminum or high-grade steel.

3. An apparatus according to claim 1, characterized in that the planar gas distributor (3) has a heater, with which it can be heated up to temperatures between 150° C. and 250° C.

4. An apparatus according to claim 1, characterized in that the susceptor (4) has a temperature controlling device, in particular a cooling device, with which the susceptor (4), and in particular the supporting surface (4′), can be cooled to temperatures as low as −30° C. and/or heated up to temperatures as high as 100° C.

5. An apparatus according to claim 4, characterized in that the susceptor (4) is \ formed as a cooling block with fluid passages (18), through which there flows a temperature control medium, which is liquid in a temperature range between −30° C. and 100° C.

6. An apparatus according to claim 1, characterized in that a plate of the planar gas distributor (3) that forms the gas discharge surface (3′) has channels (19), through which there flows a temperature control medium, which is liquid in a temperature range between 150° C. and 250° C., or has an electrically conducting conductor.

7. An apparatus according to claim 1, characterized in that a distance (A) between the supporting surface (4′) and the gas discharge surface (3′) is in a range between 10 mm and 50 mm.

8. An apparatus according to claim 1, characterized by a pressure-regulated vacuum pump, which is located downstream of the gas outlet (5) and with which an internal pressure in the deposition chamber (8) can be set between 0.05 and 0.5 mbar.

9. An apparatus according to claim 8, characterized by a cooling trap disposed between the gas outlet (5) and the vacuum pump for freezing the unpolymerized part of the monomer.

10. An apparatus according to claim 1, characterized in that connecting lines (13, 15) between the evaporator (1), the decomposition chamber (2) and the deposition chamber (8) as well as valves (14) optionally disposed there and a gas outlet line connected to the gas outlet (5) are heatable.

11. An apparatus according to claim 1, characterized in that a wall (8′) of the deposition chamber (8) can be heated by means of a heater to temperatures in a range between 150° C. and 250° C.

12. An apparatus according to claim 1, characterized by a mass flow controller (10), which can be closed by a valve (12), for metering the carrier gas.

13. An apparatus according to claim 1, characterized in that the gas discharge surface (3′) substantially corresponds to the supporting surface (4′) or protrudes beyond the edge of the substrate on each side approximately by a distance (A) between the gas discharge surface (3′) and the supporting surface (4′).

14. An apparatus according to claim 1, characterized in that the gas discharge surface (3′) or the supporting surface (4′) is larger than 0.5 m².

15. An apparatus according to claim 1, characterized in that a number of decomposition chambers (2), in particular four, each with an associated evaporator (1), are disposed vertically above a reactor housing (24) forming the deposition chamber (8).

16. An apparatus according to claim 15, characterized in that the evaporators (1) and the decomposition chambers (2) are flowed through in a vertical direction from top to bottom.

17. An apparatus according to claim 1, characterized by a heating jacket (16) surrounding the decomposition chamber (2).

18. An apparatus according to claim 1, characterized in that flow resistances of the gas lines (13, 15 and 9), defined in particular by pipe diameter, and flow resistance of the planar gas distributor (3), substantially defined by diameters and number of the gas discharge ports (6), are dimensioned such that, with a total pressure of <1 mbar in the decomposition chamber (2) and a total pressure of approximately 0.1 mbar in the deposition chamber (8), a total gas flow of at least 2000 sccm can be achieved.

19. A method for depositing one or more thin layers of polymeric material, in particular para-xylylene, or substituted para-xylylene, a solid or liquid starting material, formed in particular by a polymer, in particular a dimer, being evaporated in an evaporator (1), the starting material, in particular the dimer, being transported by means of a carrier gas from the evaporator (1) through a carrier gas supply line (13) into a decomposition chamber, in particular a pyrolysis chamber, (2) decomposed in the decomposition chamber (2), preferably pyrolytically, in particular into a monomer, the decomposition product, in particular the monomer, being transported by the carrier gas from the decomposition chamber (2) into a deposition chamber (8), in which a substrate (7) rests on a supporting surface (4′) of a susceptor (4), and flowing there through a gas inlet (3) into the deposition chamber (8), the decomposition product, in particular the monomer, being discharged in a direction perpendicular to a surface (7′) of the substrate (7) together with the carrier gas from gas discharge ports (6) of a gas discharge surface (3′), extending parallel to the supporting surface (4′), of a planar gas distributor formed by the gas inlet (3) and polymerizing on the surface (7′) of the substrate (7) as a thin layer, and the carrier gas and an unpolymerized part of the decomposition product, in particular the monomer, exiting out of the process chamber (8) from a gas outlet (5), the supporting surface (4′) being cooled and the gas discharge surface (3′) that lies opposite the supporting surface (4′) being heated in such a way that a surface temperature of the gas discharge surface (3′) is higher than a surface temperature of the supporting surface (4′),
characterized in that the carrier gas is discharged in the form of closely neighboring gas jets from the gas discharge ports (6), which are distributed over the entire gas discharge surface (3′), the gas discharge surface being highly reflective and having an emissivity of ε<0.04, and combine to form a vertical volumetric gas flow extending substantially over the entire supporting surface (4′), the substrate resting on the supporting surface (4′) in thermally conducting contact over the whole surface area, by way of which heat transferred from the actively heated gas discharge surface (3′) to the substrate (7) is conducted away into the susceptor (4) in such a way that temperatures measured at any two points on the surface (7′) of the substrate (7) differ by a maximum of 10° C.

20. A method according to claim 19, characterized in that evaporation of the starting material, in particular the dimer, in the evaporator (1) takes place at a temperature between 50° C. and 200° C.

21. A method according to claim 19, characterized in that decomposition of the starting material, in particular the dimer, into the decomposition product, in particular the monomer, in the decomposition chamber (2) takes place at temperatures between 350° C. and 700° C. and, in particular, in a pressure range of <1 mbar.

22. A method according to claim 19, characterized in that the planar gas distributor formed by the gas inlet (3) is heated to a temperature in a range from 150° C. to 250° C.

23. A method according to claim 19, characterized in that walls (8′) of the deposition chamber (8) are heated to a temperature in a range from 150° C. to 250° C.

24. A method according to claim 19, characterized in that the susceptor (4) is controlled to a temperature which lies in a range between −30° C. and 100° C.

25. A method according to claim 19, characterized in that a maximum temperature difference between two points on the supporting surface (4′) or on the substrate (7) is ±0.5° C.

26. A method according to claim 19, characterized in that the layer has a thickness of 200 nm to 400 nm or several μm.

27. A method according to claim 19, characterized in that a pressure in the deposition chamber (8) lies in a range between 0.05 mbar and 0.5 mbar.

28. A method according to claim 19, characterized in that a growth rate of the one or more layers lies in a range between 100 nm/s and 2 μm/s.

29. A method according to claim 19, characterized in that a total gas flow through the deposition chamber (8) is at least 2000 sccm, the gas inlet (3) being fed by a number of decomposition chambers (2), in particular four, through each of which there flows an equal fraction of the total gas flow.
